(19) United States
(12) Patent Application Publication
(10) Pub. No.: US 2026/0099227 A1
(43) Pub. Date: Apr. 9, 2026

(54) ELECTRONIC DEVICE

(71) Applicant: Samsung Display Co., Ltd., Yongin-si (KR)

(72) Inventor: Kyushik SHIN, Yongin-si (KR)

(21) Appl. No.: 19/279,787

(22) Filed: Jul. 24, 2025

(30) Foreign Application Priority Data
Oct. 7, 2024 (KR) 10-2024-0135403

(51) Int. Cl. G06F 3/041; G06F 3/044

(52) U.S. Cl. CPC G06F 3/0418; G06F 3/04164; G06F 3/0446; G06F 2203/04111

(57) ABSTRACT

An electronic device includes: a sensor layer; and a sensor driver electrically connected to the sensor layer. The sensor layer includes: first electrodes along a first direction; second electrodes along a second direction crossing the first direction; first trace lines electrically connected to the first electrodes; and second trace lines electrically connected to the second electrodes. Each of the second electrodes includes: a first division electrode extending in the first direction; and a second division electrode extending in the first direction, and spaced from the first division electrode in the second direction. The sensor driver includes a first circuit to: receive a first signal from the first division electrodes to generate a first intermediate coordinate signal; receive a second signal from the second division electrodes to generate a second intermediate coordinate signal; and generate a coordinate signal based on the first intermediate coordinate signal and the second intermediate coordinate signal.

### CROSS-REFERENCE TO RELATED APPLICATION

The present application claims priority to and the benefit of Korean Patent Application No. 10-2024-0135403, filed on Oct. 7, 2024, in the Korean Intellectual Property Office, the entire disclosure of which is incorporated by reference herein.

### BACKGROUND

### 1. Field

Aspects of embodiments of the present disclosure relate to an electronic device having an improved sensing performance for a touch event.

### 2. Description of the Related Art

Multimedia electronic devices, such as televisions, mobile phones, tablet computers, navigation devices, game devices, and displays for vehicles, display images, and provide a touch-based input method allowing users to more easily and intuitively input information or commands, in addition to other input methods, such as a button, a keyboard, a mouse, and the like.

### SUMMARY

Embodiments of the present disclosure may be directed to an electronic device having an improved sensing performance when a touch event occurs.

According to one or more embodiments of the present disclosure, an electronic device includes: a sensor layer including a sensing area, and a peripheral area adjacent to the sensing area; and a sensor driver electrically connected to the sensor layer. The sensor layer includes: a plurality of first electrodes along a first direction; a plurality of second electrodes along a second direction crossing the first direction; a plurality of first trace lines electrically connected to the first electrodes; and a plurality of second trace lines electrically connected to the second electrodes, and partially located in the peripheral area. Each of the second electrodes includes: a first division electrode extending in the first direction; and a second division electrode extending in the first direction, and spaced from the first division electrode in the second direction. The sensor driver includes a first circuit configured to: receive a first signal from the first division electrodes of the second electrodes to generate a first intermediate coordinate signal; receive a second signal from the second division electrodes of the second electrodes to generate a second intermediate coordinate signal; and generate a coordinate signal based on the first intermediate coordinate signal and the second intermediate coordinate signal.

In an embodiment, the first circuit may include a switch circuit configured to selectively receive either the first signal or the second signal.

In an embodiment, the first circuit may further include a first coordinate signal generator configured to receive the first signal through the switch circuit in a first section to generate the first intermediate coordinate signal, and receive the second signal in a second section following the first section in time to generate the second intermediate coordinate signal.

In an embodiment, the first circuit may further include a second coordinate signal generator configured to calculate a centroid of the first intermediate coordinate signal and the second intermediate coordinate signal to generate the coordinate signal.

In an embodiment, the sensor driver may further include a second circuit including an amplifier configured to perform a differential operation on the second signal provided from the second division electrode of one second electrode among the second electrodes, and the first signal provided from the first division electrode of another second electrode among the second electrodes to generate a differential amplified signal.

In an embodiment, the second trace lines may extend in the second direction in an area overlapping with the sensing area.

In an embodiment, the second trace lines may have a same length as each other in an area overlapping with the sensing area.

In an embodiment, the sensing area may include a plurality of sensing units along the first direction and the second direction, and each of the sensing units may overlap with one first electrode among the first electrodes and one second electrode among the second electrodes.

In an embodiment, a first maximum width in the second direction of the first division electrode may be smaller than a second maximum width in the first direction of one first electrode among the first electrodes.

In an embodiment, the first division electrode may include: a plurality of sensing patterns spaced from each other in the first direction; and a plurality of bridge patterns located at a different layer from that of the sensing patterns, and electrically connected to the sensing patterns. The second trace lines may be located at a same layer as that of the bridge patterns.

In an embodiment, the second trace lines may include: a first division trace line connected to the first division electrode of one second electrode among the second electrodes; and a second division trace line connected to the second division electrode of the one second electrode. The first division trace line and the second division trace line may be located between two bridge patterns that are closest to each other in the first direction among the bridge patterns.

In an embodiment, the second trace lines may include: a third division trace line connected to the first division electrode of another second electrode among the second electrodes; and a fourth division trace line connected to the second division electrode of the another second electrode. A first distance between the first division trace line and the second division trace line may be smaller than a second distance between the second division trace line and the third division trace line in an area overlapping with the sensing area.

According to one or more embodiments of the present disclosure, an electronic device includes: a sensor layer including a sensing area, and a peripheral area adjacent to the sensing area; and a sensor driver electrically connected to the sensor layer, the sensor layer including: a plurality of first electrodes along a first direction; a plurality of second electrodes along a second direction crossing the first direction; a plurality of first trace lines electrically connected to the first electrodes; and a plurality of second trace lines electrically connected to the second electrodes, and partially located in the peripheral area. One second electrode among the second electrodes includes: a first division electrode; and a second division electrode spaced from the first division electrode in the second direction. Another second electrode among the second electrodes includes: a third division electrode; and a fourth division electrode spaced from the third division electrode in the second direction. The first division electrode, the second division electrode, the third division electrode, and the fourth division electrode are sequentially located along the second direction, and the sensor driver is configured to perform a differential operation on a signal received from the second division electrode and a signal received from the third division electrode.

In an embodiment, the sensor driver may further include an amplifier configured to perform the differential operation on the signal received from the second division electrode and the signal received from the third division electrode to generate a differential amplified signal.

In an embodiment, the sensor driver may further include a first coordinate signal generator configured to: generate a first intermediate coordinate signal based on a signal provided from the first division electrode; and generate a second intermediate coordinate signal based on the signal provided from the second division electrode.

In an embodiment, the sensor driver may further include a second coordinate signal generator configured to calculate a centroid of the first intermediate coordinate signal and the second intermediate coordinate signal to generate a coordinate signal.

In an embodiment, the sensor driver may include a switch circuit configured to selectively receive the signal from either the first division electrode or the second division electrode.

In an embodiment, a first maximum width in the second direction of the first division electrode may be smaller than a second maximum width in the first direction of one first electrode among the first electrodes.

In an embodiment, the second trace lines may include: a first division trace line connected to the first division electrode; a second division trace line connected to the second division electrode; a third division trace line connected to the third division electrode; and a fourth division trace line connected to the fourth division electrode. A first distance between the first division trace line and the second division trace line may be smaller than a second distance between the second division trace line and the third division trace line in an area overlapping with the sensing area.

In an embodiment, the second trace lines may have a same length as each other in an area overlapping with the sensing area.

According to some embodiments of the present disclosure, an electronic device may include a sensor layer and a sensor driver that are electrically connected to each other. The sensor driver may correct coordinates using signals provided through two division trace lines, which may be electrically connected to two division electrodes overlapping with one sensing unit. Thus, an accuracy of the coordinates may be improved, and a possibility of touch malfunctions may be reduced.

According to some embodiments of the present disclosure, the sensor driver may generate a differential amplified signal through a differential operation using a signal provided through one division trace line as a differential signal of a signal provided through another division trace line of a next channel. Thus, a noise included in the signal may be removed through the differential operation.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a plan view illustrating an electronic device according to an embodiment of the present disclosure;

FIG. 2 is a block diagram illustrating an electronic device according to an embodiment of the present disclosure;

FIG. 3 is a cross-sectional view illustrating an electronic device according to an embodiment of the present disclosure;

FIG. 4 is a plan view illustrating a display layer according to an embodiment of the present disclosure;

FIG. 5 is a plan view illustrating a sensor layer according to an embodiment of the present disclosure;

FIG. 6 is an enlarged view of the area AA′ of FIG. 5 according to an embodiment of the present disclosure;

FIG. 7 is a plan view illustrating one sensing unit according to an embodiment of the present disclosure;

FIG. 8 is an enlarged view of the area AA′ of FIG. 5 according to an embodiment of the present disclosure;

FIG. 9 is a waveform diagram illustrating a first signal and a second signal according to an embodiment of the present disclosure;

FIG. 10 is a view illustrating an operation of a first circuit according to an embodiment of the present disclosure;

FIG. 11 is a waveform diagram illustrating a second signal and a third signal according to an embodiment of the present disclosure;

FIG. 12 is a view illustrating an operation of a second circuit according to an embodiment of the present disclosure; and

FIG. 13 is a view illustrating an operation of a first circuit and a second circuit according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,”respectively.

As used herein, the terms “part” and “unit” may refer to a software component or a hardware component that performs a specific function. The hardware component may include, for example, a field-programmable gate array (FPGA) or an application-specific integrated circuit (ASIC). The software component may refer to executable code and/or data used by the executable code in an addressable storage medium. Thus, the software components may be, for example, object-oriented software components, class components, and/or task components, and may include processes, functions, attributes, procedures, subroutines, segments of program code, drivers, firmware, micro codes, circuits, data, a database, data structures, tables, arrays, and/or variables.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

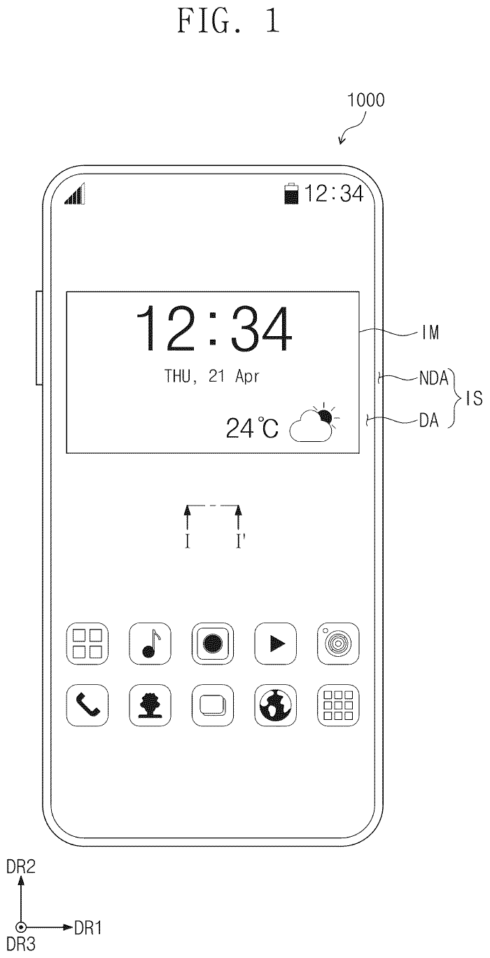

FIG. 1 is a plan view illustrating an electronic device 1000 according to an embodiment of the present disclosure.

Referring to FIG. 1, the electronic device 1000 may be a device that is activated in response to electrical signals. The electronic device 1000 may be applied to various suitable electronic items or devices, such as a mobile phone, a tablet computer, a smart watch, a notebook computer, a computer, a smart television, and the like. FIG. 1 illustrates the electronic device 1000 implemented as a mobile phone as a representative example.

The electronic device 1000 may display an image IM through a display surface IS that is parallel to or substantially parallel to each of a first direction DR1 and a second direction DR2. The display surface IS through which the image IM is displayed may correspond to a front surface of the electronic device 1000. The image IM may include a still image as well as a video. A normal line direction of the display surface IS (e.g., a thickness direction of the electronic device 1000) may correspond to a third direction DR3. Front (e.g., upper) and rear (e.g., lower) surfaces of each layer or each unit of the electronic device 1000 may be defined with respect to the third direction DR3.

The display surface IS of the electronic device 1000 may include a display area DA and a peripheral area NDA. The display area DA may be an area in which the image IM is displayed. A user may view the image IM in the display area DA. In the present embodiment, the display area DA may have a quadrangular shape with rounded vertices, but the present disclosure is not limited thereto. The display area DA may have a variety of suitable shapes, and is not particularly limited.

The peripheral area NDA may be defined adjacent to the display area DA. The peripheral area NDA may have a suitable color. The peripheral area NDA may be referred to as a non-display area or a bezel area. The peripheral area NDA may surround (e.g., around a periphery of) the display area DA. Accordingly, the display area DA may have a shape that is defined by or substantially defined by the peripheral area NDA, but the present disclosure is not limited thereto. According to an embodiment, the peripheral area NDA may be disposed to be adjacent to only one side of the display area DA, or may be omitted as needed or desired. The electronic device 1000 according to the present disclosure may include various suitable embodiments, and is not particularly limited.

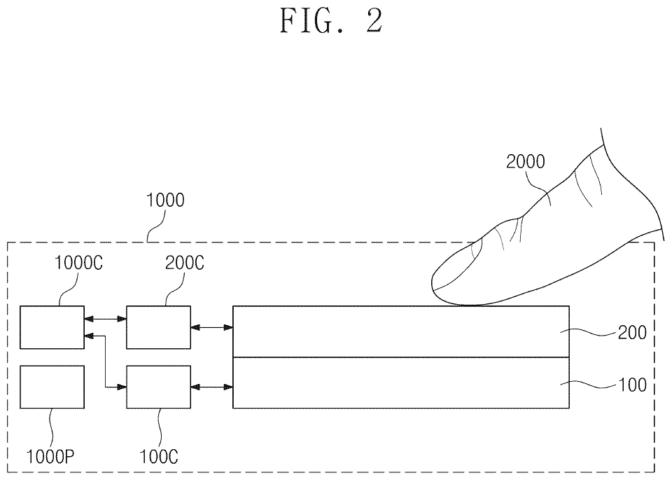

FIG. 2 is a block diagram illustrating the electronic device 1000 according to an embodiment of the present disclosure.

Referring to FIG. 2, the electronic device 1000 may include a display layer 100, a sensor layer 200, a display driver 100C, a sensor driver 200C, a main driver 1000C, and a power circuit 1000P.

The display layer 100 may have a configuration that generates or substantially generates the image. The display layer 100 may be a light emitting kind of display layer. For example, the display layer 100 may be an organic light emitting display layer, an inorganic light emitting display layer, an organic-inorganic light emitting display layer, a quantum dot display layer, a micro-LED display layer, or a nano-LED display layer.

The sensor layer 200 may be disposed on the display layer 100. The sensor layer 200 may sense an external input applied thereto from the outside. The sensor layer 200 may be an integrated sensor formed continuously in a manufacturing process of the display layer 100, or the sensor layer 200 may be an external kind of sensor that is attached to the display layer 100.

The main driver 1000C may control the overall operations of the electronic device 1000. For example, the main driver 1000C may control operations of the display driver 100C and the sensor driver 200C. The main driver 1000C may include at least one microprocessor, and may be referred to as a host. The main driver 1000C may further include a graphics controller.

The display driver 100C may drive the display layer 100. The display driver 100C may receive image data and a control signal from the main driver 1000C. The control signal may include a variety of suitable signals. As an example, the control signal may include an input vertical synchronization signal, an input horizontal synchronization signal, a main clock, a data enable signal, or the like.

The sensor driver 200C may be electrically connected to the sensor layer 200, and may drive the sensor layer 200. The sensor driver 200C may receive a control signal from the main driver 1000C. The control signal may include a clock signal of the sensor driver 200C.

The power circuit 1000P may include a power management integrated circuit (PMIC). The power circuit 1000P may generate a plurality of driving voltages to drive the display layer 100, the sensor layer 200, the display driver 100C, and the sensor driver 200C. As an example, the driving voltages may include a gate high voltage, a gate low voltage, an ELVSS voltage, an ELVDD voltage, an initialization voltage, and the like, but the present disclosure is not limited thereto.

The electronic device 1000 may sense the external input applied thereto from the outside. The electronic device 1000 may sense a passive-kind of input generated by a touch event 2000. The touch event 2000 may include all suitable kinds of input members that cause a change in a capacitance (e.g., a user's body, an input device, for example, such as a pen, and the like).

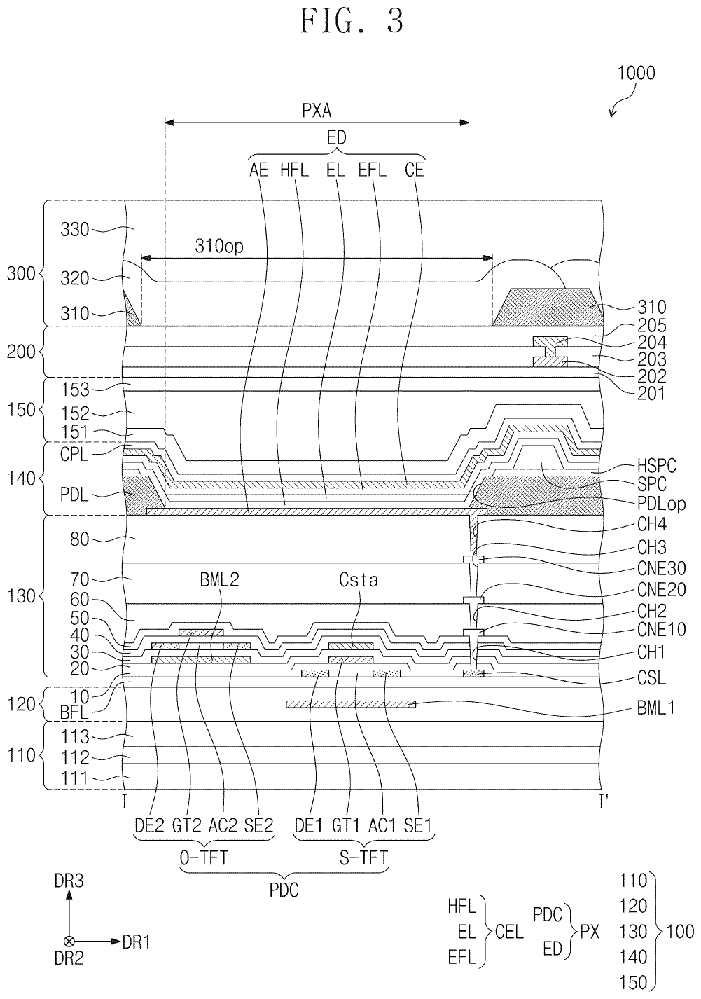

FIG. 3 is a cross-sectional view illustrating the electronic device 1000 according to an embodiment of the present disclosure. As an example, FIG. 3 is a cross-sectional view taken along the line I-I′ of FIG. 1.

Referring to FIG. 3, the electronic device 1000 may include the display layer 100, the sensor layer 200, and an anti-reflective layer 300. The display layer 100 may include a base layer 110, a barrier layer 120, a buffer layer BFL, a circuit layer 130, an element layer 140, and an encapsulation layer 150.

The base layer 110 may have a single-layer or multi-layered structure. As an example, the base layer 110 may include first, second, and third sub-base layers 111, 112, and 113. Each of the first sub-base layer 111 and the third sub-base layer 113 may include at least one of a polyimide-based resin, an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin. As used herein, the phrase “A-based resin” means that a functional group of “A” is included. As an example, each of the first and third sub-base layers 111 and 113 may include polyimide.

The second sub-base layer 112 may have a single-layer or multi-layered structure. The second sub-base layer 112 may include an inorganic material, and may include at least one of silicon oxide, silicon nitride, silicon oxynitride, or amorphous silicon. As an example, the second sub-base layer 112 may include silicon oxynitride, and silicon oxide stacked on the silicon oxynitride.

The barrier layer 120 may be disposed on the base layer 110. The barrier layer 120 may have a single-layer or multi-layered structure. The barrier layer 120 may include at least one of silicon oxide, silicon nitride, silicon oxynitride, or amorphous silicon.

The barrier layer 120 may further include a first lower light blocking layer BML1. As an example, in a case where the barrier layer 120 has a multi-layered structure, the first lower light blocking layer BML1 may be disposed between the layers forming the barrier layer 120, but the present disclosure is not limited thereto. According to an embodiment, the first lower light blocking layer BML1 may be disposed between the base layer 110 and the barrier layer 120, or may be disposed on the barrier layer 120. According to an embodiment, the first lower light blocking layer BML1 may be omitted as needed or desired. The first lower light blocking layer BML1 may be referred to as a first lower layer, a first lower metal layer, a first lower electrode layer, a first lower shield layer, a first light blocking layer, a first metal layer, a first shield layer, or a first overlap layer.

The buffer layer BFL may be disposed on the barrier layer 120. The buffer layer BFL may prevent or substantially prevent metal atoms or impurities from being diffused to a first semiconductor pattern DE1, AC1, and SE1 from the base layer 110. In addition, the buffer layer BFL may control a rate of a heat supply during a crystallization process to form the first semiconductor pattern DE1, AC1, and SE1, so that the first semiconductor pattern DE1, AC1, and SE1 may be uniformly or substantially uniformly formed.

The buffer layer BFL may include a plurality of inorganic layers. As an example, the buffer layer BFL may include a first sub-buffer layer containing silicon nitride, and a second sub-buffer layer disposed on the first sub-buffer layer and containing silicon oxide.

The circuit layer 130 may be disposed on the buffer layer BFL, and the element layer 140 may be disposed on the circuit layer 130. A pixel PX may include a pixel circuit PDC, and a light emitting element ED electrically connected to the pixel circuit PDC. The pixel circuit PDC may be included in the circuit layer 130, and the light emitting element ED may be included in the element layer 140.

In FIG. 3, a silicon thin film transistor S-TFT and an oxide thin film transistor O-TFT of the pixel circuit PDC are illustrated as a representative example. However, the transistors constituting the pixel circuit PDC may all be silicon thin film transistors S-TFT, or may all be oxide thin film transistors O-TFT.

The first semiconductor pattern DE1, AC1, and SE1 may be disposed on the buffer layer BFL. The first semiconductor pattern DE1, AC1, and SE1 may include a silicon semiconductor. As an example, the silicon semiconductor may include amorphous silicon or polycrystalline silicon. For example, the first semiconductor pattern DE1, AC1, and SE1 may include a low temperature polycrystalline silicon.

FIG. 3 shows a portion of the first semiconductor pattern DE1, AC1, and SE1 disposed on the buffer layer BFL, and the first semiconductor pattern DE1, AC1, and SE1 may be further disposed in other areas. The first semiconductor pattern DE1, AC1, and SE1 may be arranged with a suitable rule (e.g., a specific or predetermined rule) over the pixels. The first semiconductor pattern DE1, AC1, and SE1 may have different electrical properties depending on whether it is doped or not. The first semiconductor pattern DE1, AC1, and SE1 may include a first region DE1 and SE1 having a relatively high conductivity, and a second region AC1 having a relatively low conductivity. The first region DE1 and SE1 may be doped with an N-type dopant or a P-type dopant. A P-type transistor may include a doped region that is doped with the P-type dopant, and an N-type transistor may include a doped region that is doped with the N-type dopant. The second region AC1 may be a non-doped region, or a region that is doped at a concentration lower than that of the first region DE1 and SE1.

The first region DE1 and SE1 may have a conductivity greater than that of the second region AC1, and may substantially serve as an electrode or a signal line. The second region AC1 may substantially correspond to an active area (e.g., a channel) of the transistor. In other words, a portion (e.g., AC1) of the first semiconductor pattern DE1, AC1, and SE1 may be the active area of the transistor, another portion (e.g., SE1 and DE1) of the first semiconductor pattern DE1, AC1, and SE1 may be a source or a drain of the transistor, and another portion of the first semiconductor pattern DE1, AC1, and SE1 may be a connection electrode or a connection signal line.

A source area SE1, an active area AC1, and a drain area DE1 of the silicon thin film transistor S-TFT may be formed from the first semiconductor pattern DE1, AC1, and SE1. The source area SE1 and the drain area DE1 may extend in opposite directions from each other from the active area AC1 in a cross-section (e.g., in a cross-sectional view).

FIG. 3 shows a portion of a connection signal line CSL formed from the first semiconductor pattern DE1, AC1, and SE1.

The circuit layer 130 may include a plurality of inorganic layers and a plurality of organic layers. According to an embodiment, first, second, third, fourth, and fifth insulating layers 10, 20, 30, 40, and 50 that are sequentially stacked on the buffer layer BFL may be inorganic layers, and sixth, seventh, and eighth insulating layers 60, 70, and 80 may be organic layers.

The first insulating layer 10 may be disposed on the buffer layer BFL. The first insulating layer 10 may cover the first semiconductor pattern DE1, AC1, and SE1. The first insulating layer 10 may be an inorganic layer and/or an organic layer, and may have a single-layer or multi-layered structure. The first insulating layer 10 may include at least one of aluminum oxide, titanium oxide, silicon oxide, silicon nitride, silicon oxynitride, zirconium oxide, or hafnium oxide. In the present embodiment, the first insulating layer 10 may have a single-layer structure of a silicon oxide layer. Not only the first insulating layer 10, but also an insulating layer of the circuit layer 130 described in more detail below, may have a single-layer or multi-layered structure.

A gate electrode GT1 of the silicon thin film transistor S-TFT may be disposed on the first insulating layer 10. The gate electrode GT1 may be a portion of a metal pattern. The gate electrode GT1 may overlap with the active area AC1. The gate electrode GT1 may be used as a mask in a process of doping the first semiconductor pattern DE1, AC1, and SE1. The gate electrode GT1 may include titanium, silver, an alloy containing silver, molybdenum, an alloy containing molybdenum, aluminum, an alloy containing aluminum, aluminum nitride, tungsten, tungsten nitride, copper, indium tin oxide, indium zinc oxide, or the like, but the present disclosure is not limited thereto.

The second insulating layer 20 may be disposed on the first insulating layer 10, and may cover the gate electrode GT1. The second insulating layer 20 may be an inorganic layer, and may have a single-layer or multi-layered structure. The second insulating layer 20 may include at least one of silicon oxide, silicon nitride, or silicon oxynitride. According to the present embodiment, the second insulating layer 20 may have a single-layer structure of a silicon nitride layer.

The third insulating layer 30 may be disposed on the second insulating layer 20. The third insulating layer 30 may be an inorganic layer, and may have a single-layer or multi-layered structure. As an example, the third insulating layer 30 may have a multi-layered structure of a silicon oxide layer and a silicon nitride layer. One electrode Csta of a capacitor may be disposed between the second insulating layer 20 and the third insulating layer 30. In addition, the other electrode of the capacitor may be disposed between the first insulating layer 10 and the second insulating layer 20.

A second semiconductor pattern DE2, AC2, and SE2 may be disposed on the third insulating layer 30. The second semiconductor pattern DE2, AC2, and SE2 may include an oxide semiconductor. The oxide semiconductor may include a plurality of areas that are distinguished from each other depending on whether a metal oxide is reduced or not. An area DE2 and SE2 (hereinafter, referred to as a reduced area) in which the metal oxide is reduced has a conductivity greater than that of an area AC2 (hereinafter, referred to as a non-reduced area) in which the metal oxide is not reduced. The reduced area DE2 and SE2 may act as the source/drain of the transistor, or a signal line. The non-reduced area AC2 may substantially correspond to the active area (e.g., a semiconductor area or a channel) of the transistor. In other words, a portion (e.g., AC2) of the second semiconductor pattern DE2, AC2, and SE2 may be the active area of the transistor, another portion (e.g., SE2 and DE2) of the second semiconductor pattern DE2, AC2, and SE2 may be the source/drain areas of the transistor, and another portion of the second semiconductor pattern DE2, AC2, and SE2 may be a signal transmission area.

A source area SE2, an active area AC2, and a drain area DE2 of the oxide thin film transistor O-TFT may be formed from the second semiconductor pattern DE2, AC2, and SE2. The source area SE2 and the drain area DE2 may extend in opposite directions from each other from the active area AC2 in a cross-section (e.g., in a cross-sectional view).

The fourth insulating layer 40 may be disposed on the third insulating layer 30. The fourth insulating layer 40 may cover the second semiconductor pattern DE2, AC2, and SE2. The fourth insulating layer 40 may be an inorganic layer, and may have a single-layer or multi-layered structure. The fourth insulating layer 40 may include at least one of aluminum oxide, titanium oxide, silicon oxide, silicon nitride, silicon oxynitride, zirconium oxide, or hafnium oxide. In the present embodiment, the fourth insulating layer 40 may have a single-layer structure of a silicon oxide layer.

A gate electrode GT2 of the oxide thin film transistor O-TFT may be disposed on the fourth insulating layer 40. The gate electrode GT2 may be a portion of a metal pattern. The gate electrode GT2 may overlap with the active area AC2. The gate electrode GT2 may be used as a mask in a process of reducing the second semiconductor pattern.

A second lower light blocking layer BML2 may be disposed under the oxide thin film transistor O-TFT. The second lower light blocking layer BML2 may be disposed between the second insulating layer 20 and the third insulating layer 30. The second lower light blocking layer BML2 may include the same material as, and may be formed through the same process as, those of the electrode Csta of the capacitor.

The fifth insulating layer 50 may be disposed on the fourth insulating layer 40, and may cover the gate electrode GT2. The fifth insulating layer 50 may be an inorganic layer and/or an organic layer, and may have a single-layer or multi-layered structure. As an example, the fifth insulating layer 50 may have a multi-layered structure of a silicon oxide layer and a silicon nitride layer.

A first connection electrode CNE10 may be disposed on the fifth insulating layer 50. The first connection electrode CNE10 may be connected to the connection signal line CSL via a first contact hole CH1 defined through (e.g., penetrating) the first to fifth insulating layers 10 to 50.

The sixth insulating layer 60 may be disposed on the fifth insulating layer 50. A second connection electrode CNE20 may be disposed on the sixth insulating layer 60. The second connection electrode CNE20 may be connected to the first connection electrode CNE10 via a second contact hole CH2 defined through the sixth insulating layer 60.

The seventh insulating layer 70 may be disposed on the sixth insulating layer 60, and may cover the second connection electrode CNE20.

A third connection electrode CNE30 may be disposed on the seventh insulating layer 70. The third connection electrode CNE30 may be connected to the second connection electrode CNE20 via a third contact hole CH3 defined through the seventh insulating layer 70. The eighth insulating layer 80 may be disposed on the seventh insulating layer 70, and may cover the third connection electrode CNE30.

Each of the sixth insulating layer 60, the seventh insulating layer 70, and the eighth insulating layer 80 may be an organic layer. As an example, each of the sixth insulating layer 60, the seventh insulating layer 70, and the eighth insulating layer 80 may include a general-purpose polymer, such as benzocyclobutene (BCB), polyimide, hexamethyldisiloxane (HMDSO), polymethylmethacrylate (PMMA), or polystyrene (PS), a polymer derivative having a phenolic group, an acrylic-based polymer, an imide-based polymer, an aryl ether-based polymer, an amide-based polymer, a fluorine-based polymer, a p-xylene-based polymer, a vinyl alcohol-based polymer, or suitable blends thereof.

The light emitting element ED may include a first electrode AE, a first functional layer HFL, a light emitting layer EL, a second functional layer EFL, and a second electrode CE. The first functional layer HFL, the second functional layer EFL, and the second electrode CE may be commonly provided over the pixels PX. The first functional layer HFL, the light emitting layer EL, and the second functional layer EFL may be referred to as an intermediate layer CEL. The first electrode AE may be referred to as a pixel electrode or an anode, and the second electrode CE may be referred to as a common electrode or a cathode.

The first electrode AE may be disposed on the eighth insulating layer 80. The first electrode AE may be connected to the third connection electrode CNE30 electrically connected to the pixel circuit PDC via a fourth contact hole CH4 defined through the eighth insulating layer 80.

According to an embodiment of the present disclosure, the third connection electrode CNE30 may be omitted as needed or desired. In this case, the first electrode AE may be connected to the second connection electrode CNE20 after penetrating through the seventh and eighth insulating layers 70 and 80. In addition, according to an embodiment of the present disclosure, the third connection electrode CNE30 and the eighth insulating layer 80 may be omitted as needed or desired. In this case, the first electrode AE may be disposed on the seventh insulating layer 70, and may be connected to the second connection electrode CNE20 after penetrating through the seventh insulating layer 70.

The first electrode AE may be a (semi-) transmissive electrode or a reflective electrode. According to an embodiment, the first electrode AE may include a reflective layer including silver, magnesium, aluminum, platinum, palladium, gold, nickel, neodymium, iridium, chromium, or suitable compounds thereof, and a transparent or semi-transparent electrode layer formed on the reflective layer. The transparent or semi-transparent electrode layer may include at least one selected from the group consisting of indium tin oxide, indium zinc oxide, indium gallium zinc oxide, zinc oxide, indium oxide, and aluminum-doped zinc oxide. For example, the first electrode AE may have a stack structure of indium tin oxide, silver, and indium tin oxide, which are sequentially stacked.

A pixel definition layer PDL may be disposed on the eighth insulating layer 80. The pixel definition layer PDL may have a light absorbing property, and for example, may have a black color. The pixel definition layer PDL may include a black coloring agent. The black coloring agent may include a black dye or a black pigment. The black coloring agent may include a metal material, such as carbon black, chromium, or an oxide thereof.

The pixel definition layer PDL may be provided with an opening PDLop to expose a portion of the first electrode AE. In other words, the pixel definition layer PDL may cover an edge of the first electrode AE. A light emitting area PXA may be defined by the pixel definition layer PDL.

A spacer HSPC may be disposed on the pixel definition layer PDL. A protruded spacer SPC may be disposed on the spacer HSPC. The spacer HSPC and the protruded spacer SPC may be provided integrally with each other, and may include the same material as each other. As an example, the spacer HSPC and the protruded spacer SPC may be formed through the same process as each other using a halftone mask, but the present disclosure is not limited thereto. According to an embodiment, the spacer HSPC and the protruded spacer SPC may include different materials from each other, and may be formed through different processes from each other.

The first functional layer HFL may be disposed on the first electrode AE, the pixel definition layer PDL, the spacer HSPC, and the protruded spacer SPC. The first functional layer HFL may include a hole transport layer, may include a hole injection layer, or may include both the hole transport layer and the hole injection layer. The first functional layer HFL may be disposed over the entire or substantially entire display area.

The light emitting layer EL may be disposed on the first functional layer HFL, and may be disposed in an area corresponding to the opening PDLop of the pixel definition layer PDL. The light emitting layer EL may include an organic material, an inorganic material, or an organic-inorganic material, which emits light having a desired color (e.g., a selected or predetermined color).

The second functional layer EFL may be disposed on the first functional layer HFL, and may cover the light emitting layer EL. The second functional layer EFL may include an electron transport layer, may include an electron injection layer, or may include both the electron transport layer and the electron injection layer. The second functional layer EFL may be disposed over the entire or substantially entire display area.

The second electrode CE may be disposed on the second functional layer EFL. The second electrode CE may be disposed in the display area.

The element layer 140 may further include a capping layer CPL disposed on the second electrode CE. The capping layer CPL may improve a light emission efficiency by a principle of constructive interference. The capping layer CPL may be an organic capping layer including an organic material, an inorganic capping layer including an inorganic material, or a composite capping layer including the organic material and the inorganic material. For example, the capping layer may include carbocyclic compounds, heterocyclic compounds, amine group-containing compounds, porphine derivatives, phthalocyanine derivatives, naphthalocyanine derivatives, alkali metal complexes, alkaline earth metal complexes, or any suitable combination thereof. The carbocyclic compounds, the heterocyclic compounds, and the amine group-containing compounds may optionally be substituted with substituents including oxygen (O), nitrogen (N), sulfur(S), selenium (Se), silicon (Si), fluorine (F), chlorine (Cl), bromine (Br), iodine (I), or any suitable combination thereof.

The encapsulation layer 150 may be disposed on the element layer 140. The encapsulation layer 150 may include a first inorganic encapsulation layer 151, an organic encapsulation layer 152, and a second inorganic encapsulation layer 153, which are sequentially stacked. The first and second inorganic encapsulation layers 151 and 153 may protect the element layer 140 from moisture and oxygen, and the organic layer 152 may protect the element layer 140 from a foreign substance such as dust particles.

According to an embodiment of the present disclosure, a low refractive index layer may be further disposed between the capping layer CPL and the encapsulation layer 150. The low refractive index layer may include fluorinated lithium. The low refractive index layer may be formed by a thermal deposition method.

The sensor layer 200 may be disposed on the display layer 100. The sensor layer 200 may be referred to as a sensor, an input sensing layer, or an input sensing panel. The sensor layer 200 may include a sensor base layer 201, a first sensor conductive layer 202, an intermediate insulating layer 203, a second sensor conductive layer 204, and a cover layer 205.

The sensor base layer 201 may be disposed directly on the display layer 100. The sensor base layer 201 may be an inorganic layer including at least one of silicon nitride, silicon oxynitride, or silicon oxide. According to an embodiment, the sensor base layer 201 may be an organic layer including an epoxy resin, an acrylic resin, or an imide-based resin. The sensor base layer 201 may have a single-layer structure, or a multi-layered structure of a plurality of layers stacked in the third direction DR3.

Each of the first sensor conductive layer 202 and the second sensor conductive layer 204 may have a single-layer structure, or a multi-layered structure of a plurality of layers stacked in the third direction DR3.

The conductive layer having the single-layer structure may include a metal layer or a transparent conductive layer. The metal layer may include molybdenum (Mo), silver (Ag), titanium (Ti), copper (Cu), aluminum (Al), or suitable alloys thereof. The transparent conductive layer may include a transparent conductive oxide, such as indium tin oxide (ITO), indium zinc oxide (IZO), zinc oxide (ZnO), indium zinc tin oxide (ITZO), or the like. In addition, the transparent conductive layer may include a conductive polymer, such as poly(3,4-ethylenedioxythiophene) (PEDOT), a metal nanowire, graphene, or the like.

The conductive layer having the multi-layered structure may include a plurality of metal layers. The metal layers may have a three-layered structure of titanium/aluminum/titanium. The conductive layer having the multi-layered structure may include at least one metal layer and at least one transparent conductive layer.

The intermediate insulating layer 203 may be disposed between the first sensor conductive layer 202 and the second sensor conductive layer 204. The intermediate insulating layer 203 may include an organic layer. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

In addition, the intermediate insulating layer 203 may include an inorganic layer. The inorganic layer may include at least one of aluminum oxide, titanium oxide, silicon oxide, silicon nitride, silicon oxynitride, zirconium oxide, or hafnium oxide.

The cover layer 205 may be disposed on the intermediate insulating layer 203, and may cover the second sensor conductive layer 204. The second sensor conductive layer 204 may include a conductive pattern. The cover layer 205 may cover the conductive pattern, and may reduce a possibility of an occurrence of a damage in the conductive pattern in a subsequent process. The cover layer 205 may include an inorganic material. As an example, the cover layer 205 may include silicon nitride, but the present disclosure is not limited thereto. According to an embodiment of the present disclosure, the cover layer 205 may be omitted as needed or desired.

The anti-reflective layer 300 may be disposed on the sensor layer 200. The anti-reflective layer 300 may include a division layer 310, a plurality of color filters 320, and a planarization layer 330.

The division layer 310 may overlap with the conductive pattern of the second sensor conductive layer 204. The cover layer 205 may be disposed between the division layer 310 and the second sensor conductive layer 204. The division layer 310 may prevent or substantially prevent external light from being reflected by the second sensor conductive layer 204. Materials for the division layer 310 is not particularly limited, as long as the materials absorb light. The division layer 310 may have a black color, and may include a black coloring agent. The black coloring agent may include a black dye or a black pigment. The black coloring agent may include a metal material, such as carbon black, chromium, or an oxide thereof.

A division opening 310op may be defined through (e.g., may penetrate) the division layer 310. The division opening 310op may overlap with the light emitting layer EL. The color filter 320 may correspond to the division opening 310op. The color filter 320 may transmit light provided from the light emitting layer EL overlapping with the color filter 320.

The planarization layer 330 may cover the division layer 310 and the color filter 320. The planarization layer 330 may include an organic material, and may provide a flat or substantially flat upper surface. According to an embodiment, the planarization layer 330 may be omitted as needed or desired.

According to an embodiment, the anti-reflective layer 300 may include a reflective control layer instead of the color filters 320. As an example, the color filter 320 may be omitted from the structure illustrated in FIG. 3, and the reflective control layer may be provided in place of the color filter 320. The reflective control layer may selectively absorb light in some bands of the light reflected from inside the display panel and/or electronic device, or light incident from outside the display panel and/or electronic device.

As an example, the reflective control layer may absorb light in a first wavelength range from about 490 nm to about 505 nm, and light in a second wavelength range from about 585 nm to about 600nm, and thus, a light transmittance in the first wavelength range and in the second wavelength range may be about 40% or less. The reflective control layer may absorb light with a wavelength outside the wavelength ranges of red, green, and blue light emitted from the light emitting layer EL. As described above, because the reflective control layer absorbs light with a wavelength outside the wavelength ranges of red, green, and blue light emitted from the light emitting layer EL, the brightness of the display panel and/or electronic device may be prevented or substantially prevented from being lowered. In addition, the light emission efficiency of the display panel and/or electronic device may be prevented or substantially prevented from being lowered, and the visibility of the display panel and/or electronic device may be improved.

The reflective control layer may be an organic material layer containing a dye, a pigment, or a suitable combination thereof. The reflective control layer may include a tetraazaporphyrin-based compound, a porphyrin-based compound, a metal porphyrin-based compound, an oxazine-based compound, a squarylium-based compound, a triarylmethane-based compound, a polymethine-based compound, an anthraquinone-based compound, a phthalocyanine-based compound, an azo-based compound, a perylene-based compound, a xanthene-based compound, a diimmonium-based compound, a dipyrromethene-based compound, a cyanine-based compound, and/or suitable combinations thereof.

According to an embodiment, the reflective control layer may have a transmittance from about 64% to about 72%. The transmittance of the reflective control layer may be controlled depending on a content of the pigment and/or the dye included in the reflective control layer.

According to an embodiment, the anti-reflective layer 300 may include a retarder and/or a polarizer. The anti-reflective layer 300 may include at least a polarizing film. In this case, the anti-reflective layer 300 may be attached to the sensor layer 200 by an adhesive layer.

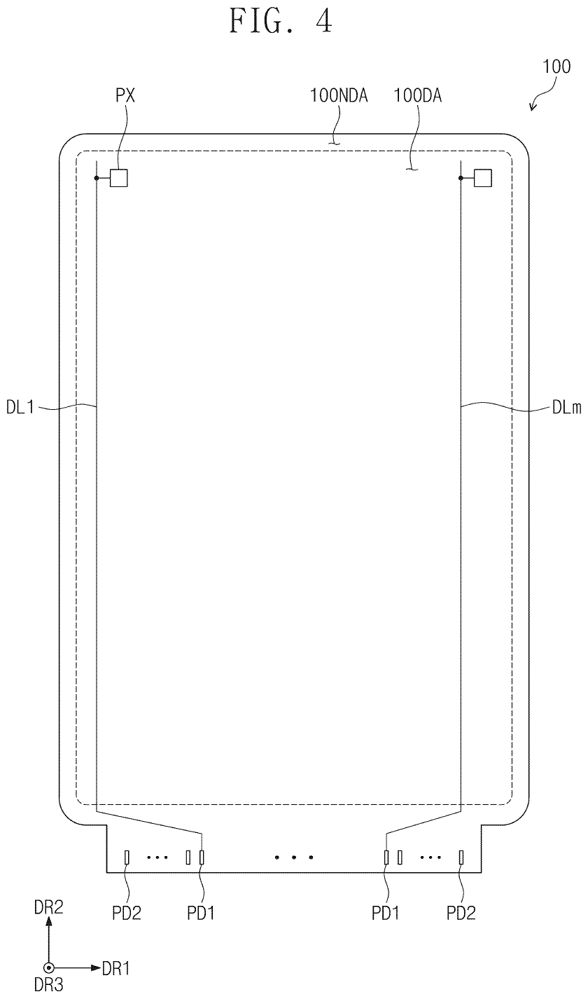

FIG. 4 is a plan view illustrating the display layer 100 according to an embodiment of the present disclosure.

Referring to FIG. 4, the display layer 100 may include a display area 100DA for displaying the image, and a peripheral area 100NDA adjacent to the display area 100DA. The display area 100DA may correspond to the display area DA (e.g., refer to FIG. 1) of the electronic device 1000, and the peripheral area 100NDA may correspond to the peripheral area NDA of the electronic device 1000. As used herein, the expression “an area/portion corresponds to another area/portion” means that the area/portion overlaps with the other area/portion, however, the areas and portions are not limited to having the same size as each other.

FIG. 4 illustrates some components included in the display layer 100. The display layer 100 may include a plurality of pixels PX, a plurality of lines DL1 to DLm, a plurality of first pads PD1, and a plurality of second pads PD2, where m is an integer greater than 1. The display layer 100 may further include other suitable components in addition to the components illustrated in FIG. 4.

The display area 100DA and the peripheral area 100NDA may be distinguished from each other by a presence or an absence of the pixels PX. The pixels PX may be arranged in the display area 100DA, the lines DL1 to DLm connected to the pixels PX may be arranged in the display area 100DA and the peripheral area 100NDA, and the first pads PD1 and the second pads PD2 may be arranged in the peripheral area 100NDA. According to an embodiment of the present disclosure, a driving chip may be mounted in the peripheral area 100NDA, or a flexible circuit film on which a driving chip is mounted may be electrically connected to the first pads PD1.

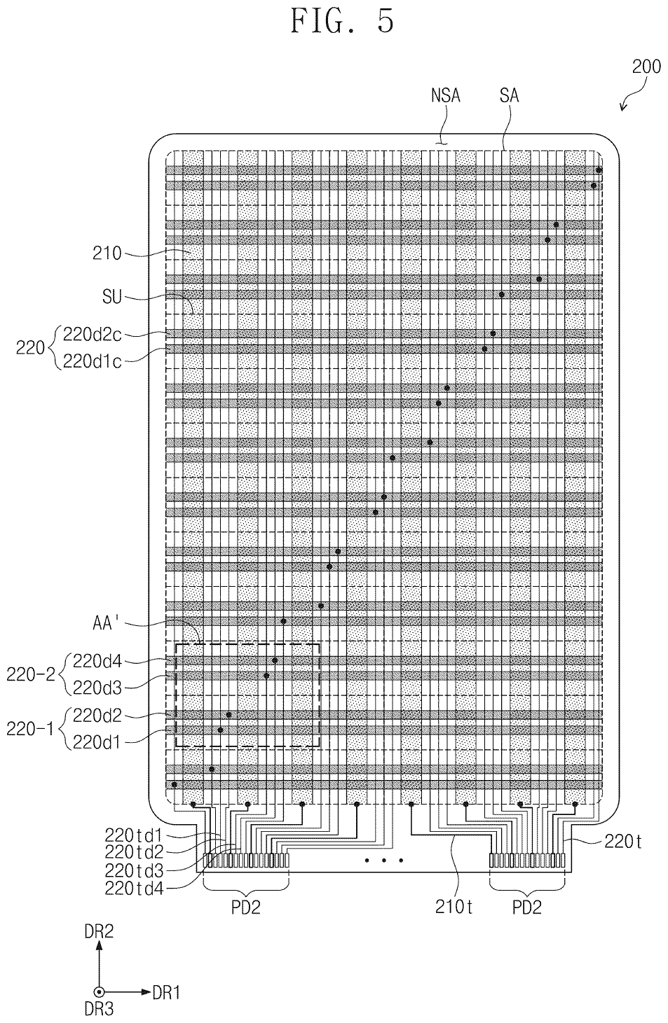

FIG. 5 is a plan view illustrating the sensor layer 200 according to an embodiment of the present disclosure.

Referring to FIG. 5, the sensor layer 200 may include a plurality of first electrodes 210 and a plurality of second electrodes 220.

The first electrodes 210 may be arranged along the first direction DR1, and the second electrodes 220 may be arranged along the second direction DR2 intersecting or crossing the first direction DR1. Each of the first electrodes 210 may extend in the second direction DR2, and each of the first electrodes 210 may intersect or cross the second electrodes 220. Each of the second electrodes 220 may extend in the first direction DR1, and each of the second electrodes 220 may intersect or cross the first electrodes 210.

A sensing area SA and a peripheral area NSA adjacent to the sensing area SA may be defined in the sensor layer 200. The sensing area SA may correspond to the display area 100DA of the display layer 100 (e.g., refer to FIG. 4), and the peripheral area NSA may correspond to the peripheral area 100NDA of the display layer 100. The first electrodes 210 and the second electrodes 220 may overlap with the sensing area SA.

According to an embodiment, each of the second electrodes 220 may include two division electrodes. Accordingly, the number of the division electrodes may be two times greater than the number of the second electrodes 220. Each of the second electrodes 220 may include a first division electrode 220d1c and a second division electrode 220d2c. According to an embodiment, the sensor driver 200C (e.g., refer to FIG. 2) may calculate coordinates using signals provided from the first division electrodes 220d1c and the second division electrodes 220d2c of the second electrodes 220. In this case, an accuracy of the coordinates may be improved as the coordinates are corrected or a noise included in the signals is removed, and thus, a possibility of touch malfunctions may also be reduced.

Hereinafter, the first division electrode 220d1c and the second division electrode 220d2c of one second electrode 220-1 among the second electrodes 220 will be referred to as a first division electrode 220d1 and a second division electrode 220d2, respectively. The first division electrode 220d1c and the second division electrode 220d2c of another second electrode 220-2 among the second electrodes 220 will be referred to as a third division electrode 220d3 and a fourth division electrode 220d4, respectively.

Each of the first division electrode 220d1 and the second division electrode 220d2 may extend in the first direction DR1, and the first division electrode 220d1 and the second division electrode 220d2 may be spaced apart from each other in the second direction DR2. Each of the third division electrode 220d3 and the fourth division electrode 220d4 may extend in the first direction DR1, and the third division electrode 220d3 and the fourth division electrode 220d4 may be spaced apart from each other in the second direction DR2. The first division electrode 220d1, the second division electrode 220d2, the third division electrode 220d3, and the fourth division electrode 220d4 may be sequentially arranged along the second direction DR2.

The first electrodes 210 may correspond to channels, respectively. The second electrodes 220 may correspond to channels, respectively. An area where one first electrode 210 intersects or crosses one second electrode 220 may be defined as one sensing node or one sensing unit. Accordingly, one first electrode 210 and two division electrodes (e.g., one first electrode 210, the first division electrode 220d1, and the second division electrode 220d2) may overlap with one sensing node.

FIG. 5 illustrates eight first electrodes 210 and twelve second electrodes 220 as a representative example, but the number of the first electrodes 210 and the number of the second electrodes 220 are not limited thereto or thereby. As an example, the number of the first electrodes 210 and the number of the second electrodes 220 may be variously modified depending on an aspect ratio or a screen size of the electronic device 1000 (e.g., refer to FIG. 1).

The sensor layer 200 may further include a plurality of first trace lines 210t and a plurality of second trace lines 220t. The first trace lines 210t may be electrically connected to the first electrodes 210, and the second trace lines 220t may be electrically connected to the second electrodes 220.

According to an embodiment, each of the second trace lines 220t may include two division trace lines. As an example, one second trace line 220t among the second trace lines 220t may include a first division trace line 220td1 and a second division trace line 220td2. The first division trace line 220td1 may be connected to the first division electrode 220d1 in an area overlapping with the sensing area SA, and the second division trace line 220td2 may be connected to the second division electrode 220d2 in an area overlapping with the sensing area SA.

In addition, another second trace line among the second trace lines 220t may include a third division trace line 220td3 and a fourth division trace line 220td4. The third division trace line 220td3 may be connected to the third division electrode 220d3 in an area overlapping with the sensing area SA, and the fourth division trace line 220td4 may be connected to the fourth division electrode 220d4 in an area overlapping with the sensing area SA.

FIG. 5 illustrates a connection relationship between the first trace lines 210t and the first electrodes 210, and between the second trace lines 220t and the second electrodes 220, as a representative example, but the present disclosure is not limited thereto. The connection relationship between the first trace lines 210t and the first electrodes 210, and between the second trace lines 220t and the second electrodes 220 may be variously modified as needed or desired.

According to an embodiment, the second trace lines 220t may extend in the second direction DR2 in the area overlapping with the sensing area SA. As an example, the first division trace line 220td1, the second division trace line 220td2, the third division trace line 220td3, and the fourth division trace line 220td4 may extend in the second direction DR2. In this case, the second trace lines 220t may have the same or substantially the same length as each other in the area overlapping with the sensing area SA.

According to an embodiment, a portion of the second trace lines 220t may be disposed in the sensing area SA. Another portion of the second trace lines 220t may be disposed in the peripheral area NSA adjacent to the sensing area SA in the second direction DR2. In addition, according to an embodiment, the second trace lines 220t may not be disposed in the peripheral area NSA adjacent to the sensing area SA in the first direction DR1. Accordingly, a size of the peripheral area NSA may be reduced. As a result, an area occupied by the peripheral area NDA (e.g., refer to FIG. 1) in the display surface IS of the electronic device 1000 may be reduced, and a narrower bezel may be implemented.

According to an embodiment, one of each of the first trace lines 210t and one end of each of the second trace lines 220t may be electrically connected to the second pads PD2. FIG. 5 illustrates a structure in which the second pads PD2 are arranged along the first direction DR1 as a representative example, but the present disclosure is not limited thereto. The arrangement of the second pads PD2 may be variously modified as needed or desired.

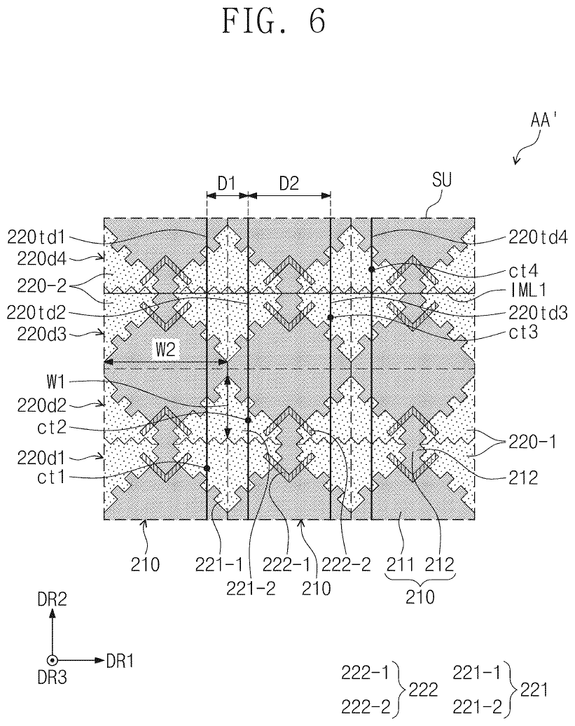

FIG. 6 is an enlarged view of the area AA′ of FIG. 5 according to an embodiment of the present disclosure. In FIG. 6, the same reference numerals are used to denote the same or substantially the same (or similar) elements as those described above with reference to FIG. 5, and thus, redundant description thereof may not be repeated hereinafter.

Referring to FIGS. 5 and 6, the sensing area SA of the sensor layer 200 may include a plurality of sensing units (e.g., a plurality of sensing regions) SU arranged along the first direction DR1 and the second direction DR2. Each of the sensing units SU may overlap with one first electrode 210 among the first electrodes 210 and one second electrode 220 among the second electrodes 220.

FIG. 6 illustrates six sensing units SU as a representative example, and a portion of three first electrodes 210 and a portion of two second electrodes 220-1 and 220-2 are illustrated. In other words, a portion of the first, second, third, and fourth division electrodes 220d1, 220d2, 220d3, and 220d4 is illustrated, and a portion of the first, second, third, and fourth division trace lines 220td1, 220td2, 220td3, and 220td4 electrically connected to the first, second, third, and fourth division electrodes 220d1, 220d2, 220d3, and 220d4, respectively, is illustrated.

According to an embodiment, the second electrode 220 may include a plurality of sensing patterns 221 and a plurality of bridge patterns 222. As an example, the first division electrode 220d1 of one second electrode 220 may include first sensing patterns 221-1 and first bridge patterns 222-1, which are spaced apart from each other in the first direction DR1. The second division electrode 220d2 of the one second electrode 220 may include second sensing patterns 221-2 and second bridge patterns 222-2, which are spaced apart from each other in the first direction DR1.

The first sensing patterns 221-1 and the second sensing patterns 221-2 may all be referred to as sensing patterns 221, and the first bridge patterns 222-1 and the second bridge patterns 222-2 may all be referred to as bridge patterns 222. Hereinafter with reference to FIG. 6, the sensing patterns 221 and the bridge patterns 222 of the first division electrode 220d1 and the second division electrode 220d2 will be described in more detail as a representative example, and the third division electrode 220d3 and the fourth division electrode 220d4 may be the same or substantially the same as (or similar to) the first division electrode 220d1 and the second division electrode 220d2, and thus, redundant description thereof may not be repeated.

According to an embodiment, the first bridge patterns 222-1 and the second bridge patterns 222-2 may be spaced apart from each other in the second direction DR2, and may be symmetrical or substantially symmetrical with each other about an imaginary line IML1 extending in the first direction DR1.

Referring to the first division electrode 220d1, the first sensing patterns 221-1 may be spaced apart from each other in the first direction DR1, and the first bridge patterns 222-1 may electrically connect the first sensing patterns 221-1 that are adjacent to each other. FIG. 6 illustrates a structure in which two first sensing patterns 221-1 adjacent to each other are electrically connected to each other by one first bridge pattern 222-1 as a representative example, but the present disclosure is not limited thereto.

Each of the first electrodes 210 may extend in the second direction DR2, and may include a sensing portion 211 and a connection portion 212. The sensing portion 211 and the connection portion 212 may be disposed at a same layer as each other, and may be integrally provided with each other. The connection portion 212 may be insulated from the first bridge pattern 222-1 and the second bridge pattern 222-2, while intersecting or crossing the first bridge pattern 222-1 and the second bridge pattern 222-2.

Each of the first, second, third, and fourth division trace lines 220td1, 220td2, 220td3, and 220td4 may be electrically connected to a corresponding one of the first, second, third, and fourth division electrodes 220d1, 220d2, 220d3, and 220d4. As an example, the first division trace line 220td1 may be electrically connected to the first division electrode 220d1 through a first contact ct1, the second division trace line 220td2 may be electrically connected to the second division electrode 220d2 through a second contact ct2, the third division trace line 220td3 may be electrically connected to the third division electrode 220d3 through a third contact ct3, and the fourth division trace line 220td4 may be electrically connected to the fourth division electrode 220d4 through a fourth contact ct4.

According to an embodiment, the sensing patterns 221 and the bridge patterns 222 may be disposed at different layers from each other. In addition, the first, second, third, and fourth division trace lines 220td1, 220td2, 220td3, and 220td4 and the bridge patterns 222 may be disposed at a same layer as each other. Referring to FIG. 3 together with FIG. 6, the sensing patterns 221 may be included in the second sensor conductive layer 204, and the bridge patterns 222 and the first, second, third, and fourth division trace lines 220td1, 220td2, 220td3, and 220td4 may be included in the first sensor conductive layer 202.

According to an embodiment, the first division trace line 220td1 and the second division trace line 220td2 may be disposed between two bridge patterns 222 that are closest to each other in the first direction DR1 among the bridge patterns 222, and the third division trace line 220td3 and the fourth division trace line 220td4 may be disposed between two other bridge patterns 222 that are closest to each other in the first direction DR1 among the bridge patterns 222. In addition, the second division trace line 220td2 and the third division trace line 220td3 may be spaced apart from each other, and one bridge pattern 222 may be disposed between the second division trace line 220td2 and the third division trace line 220td3.

In other words, in the area overlapping with the sensing area SA, a first distance D1 between the first division trace line 220td1 and the second division trace line 220td2 may be smaller than a second distance D2 between the second division trace line 220td2 and the third division trace line 220td3.

According to an embodiment, the first, second, third, and fourth division electrodes 220d1, 220d2, 220d3, and 220d4 may be obtained by dividing each of two second electrodes 220 into two portions. Accordingly, a maximum width W1 in the second direction DR2 of each of the first, second, third, and fourth division electrodes 220d1, 220d2, 220d3, and 220d4 may correspond to half of a maximum width in the second direction DR2 of each of the second electrodes 220. In addition, the maximum width W1 in the second direction DR2 of each of the first, second, third, and fourth division electrodes 220d1, 220d2, 220d3, and 220d4 may be smaller than a maximum width W2 in the first direction DR1 of one first electrode 210 among the first electrodes 210. As an example, a first width W1 that is the maximum width in the second direction DR2 of the first division electrode 220d1 may be smaller than a second width W2 that is the maximum width in the first direction DR1 of one first electrode 210 among the first electrodes 210.

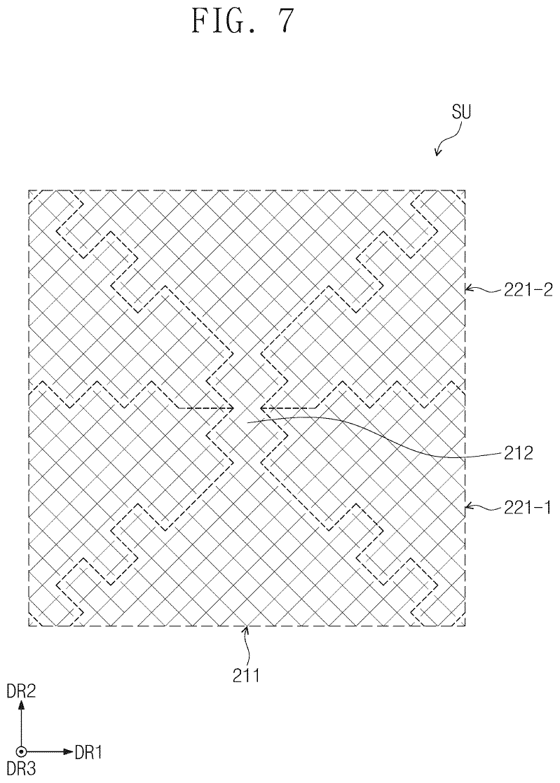

FIG. 7 is a plan view illustrating one sensing unit SU according to an embodiment of the present disclosure.

Referring to FIGS. 3, 6, and 7, the sensing portion 211 included in one first electrode 210, and the first and second sensing patterns 221-1 and 221-2 included in the first division electrode 220d1 and the second division electrode 220d2, respectively, are illustrated in FIG. 7 as a representative example.

According to an embodiment, the components illustrated in FIG. 7 may be components included in the second sensor conductive layer 204 illustrated in FIG. 3. Accordingly, the bridge patterns 222 that are not illustrated in FIG. 7 may be included in the first sensor conductive layer 202. In other words, the sensor layer 200 may have a bottom bridge structure, however, the present disclosure is not limited to the bottom bridge structure. As an example, the components illustrated in FIG. 7 may be included in the first sensor conductive layer 202, and in this case, the sensor layer 200 may have a structure in which the sensing patterns 221 are disposed closer to the display layer 100 than the bridge patterns 222 are. Therefore, the sensor layer 200 may have a top bridge structure.

According to an embodiment, each of the sensing portion 211, the first sensing patterns 221-1, and the second sensing patterns 221-2 may have a mesh structure. In addition, the sensing portion 211, the first sensing patterns 221-1, and the second sensing patterns 221-2 may be electrically separated from each other by a boundary cutting the mesh structure. In FIG. 7, the boundary cutting the mesh structure is represented by a dotted line.

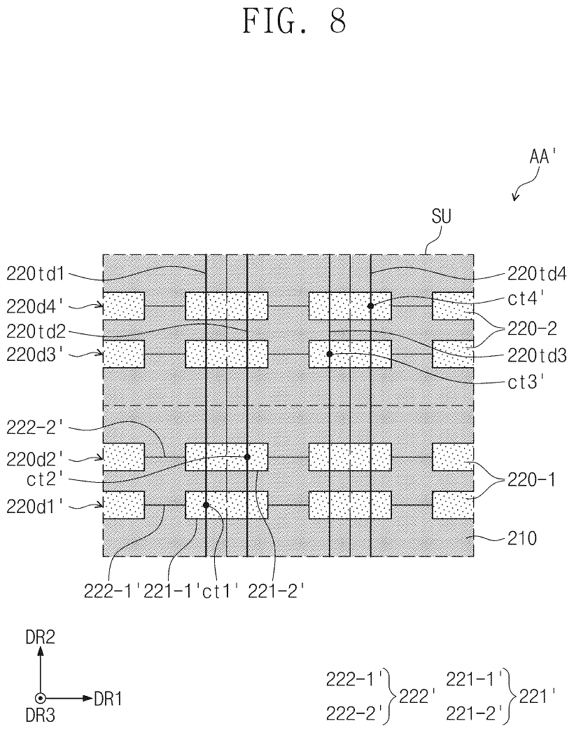

FIG. 8 is an enlarged view of the area AA′ of FIG. 5 according to an embodiment of the present disclosure.

Referring to FIGS. 5 and 8, six sensing units SU are illustrated as a representative example in FIG. 8, and a portion of three first electrodes 210 and a portion of two second electrodes 220-1 and 220-2 are illustrated. In other words, a portion of first, second, third, and fourth division electrodes 220d1′, 220d2′, 220d3′, and 220d4′ is illustrated, and a portion of first, second, third, and fourth division trace lines 220td1, 220td2, 220td3, and 220td4 respectively and electrically connected to the first, second, third, and fourth division electrodes 220d1′, 220d2′, 220d3′, and 220d4′ is illustrated.

According to an embodiment, the second electrode 220 may include a plurality of sensing patterns 221′ and a plurality of bridge patterns 222′. As an example, the first division electrode 220d1′ of one second electrode 220 may include first sensing patterns 221-1′ and first bridge patterns 222-1′, which are spaced apart from each other in the first direction DR1. The second division electrode 220d2′ of one second electrode 220 may include second sensing patterns 221-2′ and second bridge patterns 222-2′, which are spaced apart from each other in the first direction DR1.

The first sensing patterns 221-1′ and the second sensing patterns 221-2′ may all be referred to as sensing patterns 221′, and the first bridge patterns 222-1′ and the second bridge patterns 222-2′ may all be referred to as bridge patterns 222′. In FIG. 8, the sensing patterns 221′ and the bridge patterns 222′ of the first division electrode 220d1′ and the second division electrode 220d2′ are shown as a representative example, and the third division electrode 220d3′ and the fourth division electrode 220d4′ may be the same or substantially the same as the first division electrode 220d1′ and the second division electrode 220d2′, and thus, redundant description thereof may not be repeated hereinafter.

The first, second, third, and fourth division trace lines 220td1, 220td2, 220td3, and 220td4 may be electrically connected to the first, second, third, and fourth division electrodes 220d1′, 220d2′, 220d3′, and 220d4′, respectively. As an example, the first division trace line 220td1 may be electrically connected to the first division electrode 220d1′ through a first contact ct1′, the second division trace line 220td2 may be electrically connected to the second division electrode 220d2′ through a second contact ct2′, the third division trace line 220td3 may be electrically connected to the third division electrode 220d3′ through a third contact ct3′, and the fourth division trace line 220td4 may be electrically connected to the fourth division electrode 220d4′ through a fourth contact ct4′.

According to an embodiment, unlike that of FIG. 6, each of the first sensing patterns 221-1′ and each of the second sensing patterns 221-2′ of FIG. 8 may have a bar structure. In addition, the first electrodes 210, the first sensing patterns 221-1′, and the second sensing patterns 221-2′ may be electrically separated from each other.

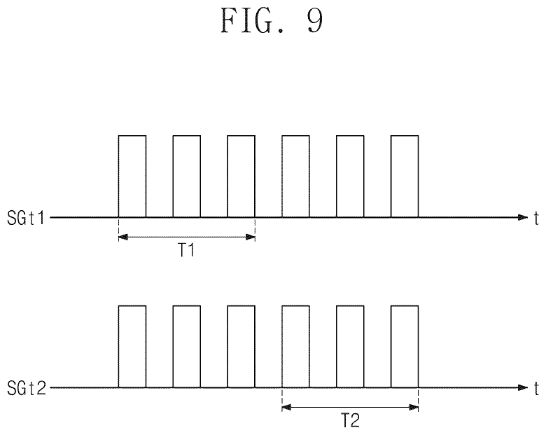

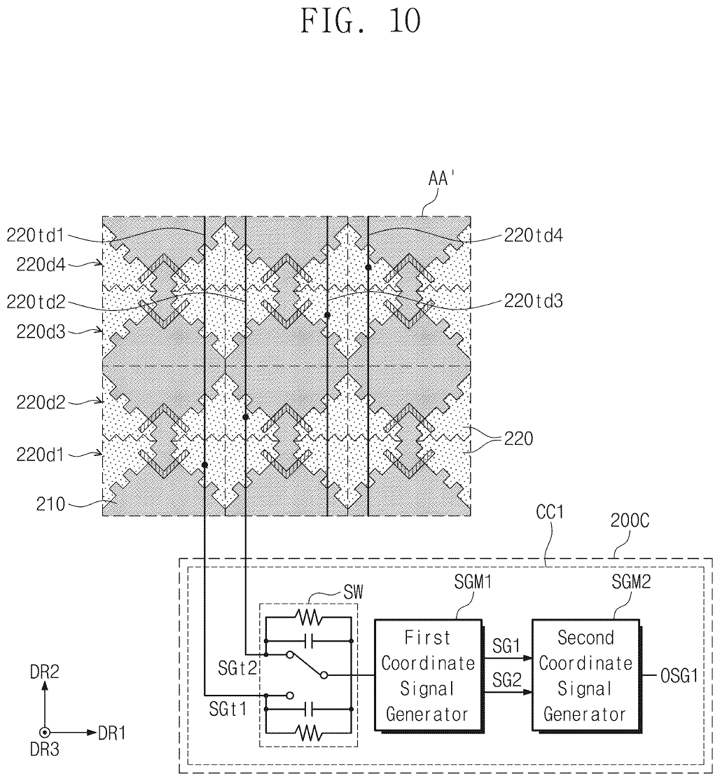

FIG. 9 is a waveform diagram illustrating a first signal SGt1 and a second signal SGt2 according to an embodiment of the present disclosure. FIG. 10 is a view illustrating an operation of a first circuit CC1 according to an embodiment of the present disclosure.

FIG. 9 illustrates a first section T1 and a second section T2, which are different from each other according to time. FIG. 10 illustrates the area AA′ of the sensor layer 200 illustrated in FIG. 6, and a portion of the sensor driver 200C as a representative example. In FIG. 10, the same reference numerals are used to denote the same or substantially the same (or similar) elements as those described above with reference to FIG. 6, and thus, redundant description thereof may not be repeated hereinafter.

Referring to FIGS. 2, 5, 9, and 10, the sensor driver 200C may include the first circuit CC1. The first circuit CC1 may include a switch circuit SW, a first coordinate signal generator SGM1, and a second coordinate signal generator SGM2.

The switch circuit SW may operate to selectively receive either the first signal SGt1 or the second signal SGt2.

The first signal SGt1 may be provided from the first division electrode 220d1 through the first division trace line 220td1 electrically connected to the first division electrode 220d1. The second signal SGt2 may be provided from the second division electrode 220d2 through the second division trace line 220td2 electrically connected to the second division electrode 220d2. The switch circuit SW may electrically connect the first coordinate signal generator SGM1 to the first division electrode 220d1, or the first coordinate signal generator SGM1 to the second division electrode 220d2.

The first coordinate signal generator SGM1 may receive the first signal SGt1 from the first division electrodes 220d1c of the second electrodes 220 to generate a first intermediate coordinate signal SG1. In addition, the first coordinate signal generator SGM1 may receive the second signal SGt2 from the second division electrodes 220d2c of the second electrodes 220 to generate a second intermediate coordinate signal SG2. In FIG. 10, the first signal SGt1 provided through the first division trace line 220td1 electrically connected to the first division electrode 220d1 and the second signal SGt2 provided through the second division trace line 220td2 electrically connected to the second division electrode 220d2 are illustrated as a representative example.

According to an embodiment, the first coordinate signal generator SGM1 may receive the first signal SGt1 through the switch circuit SW in the first section T1, and may receive the second signal SGt2 through the switch circuit SW in the second section T2. In this case, the second section T2 may immediately follow the first section T1 in time. Accordingly, the first coordinate signal generator SGM1 may generate the first intermediate coordinate signal SG1 based on the first signal SGt1, and then the first coordinate signal generator SGM1 may receive the second signal SGt2 to generate the second intermediate coordinate signal SG2.

According to an embodiment, the sensor driver 200C may store relative position information or coordinate information with respect to the first division electrode 220d1 and the second division electrode 220d2. Therefore, the second coordinate signal generator SGM2 may generate a coordinate signal OSG1 by calculating a centroid of the first intermediate coordinate signal SG1 and the second intermediate coordinate signal SG2.

According to an embodiment, the first circuit CC1 may correct the coordinates using the signals SGt1 and SGt2 provided through two division trace lines 220td1 and 220td2 that are electrically connected to two division electrodes 220d1 and 220d2 overlapping with one sensing unit SU. Accordingly, according to an embodiment of the present disclosure, the coordinates calculated may have an improved accuracy and a reduced possibility of malfunctions during the touch event 2000 when compared to coordinates calculated from a signal provided through a single trace line electrically connected to a single electrode overlapping with one sensing unit SU.

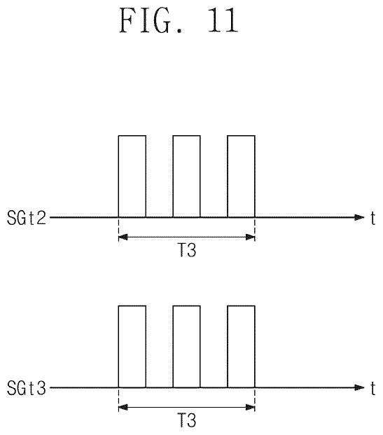

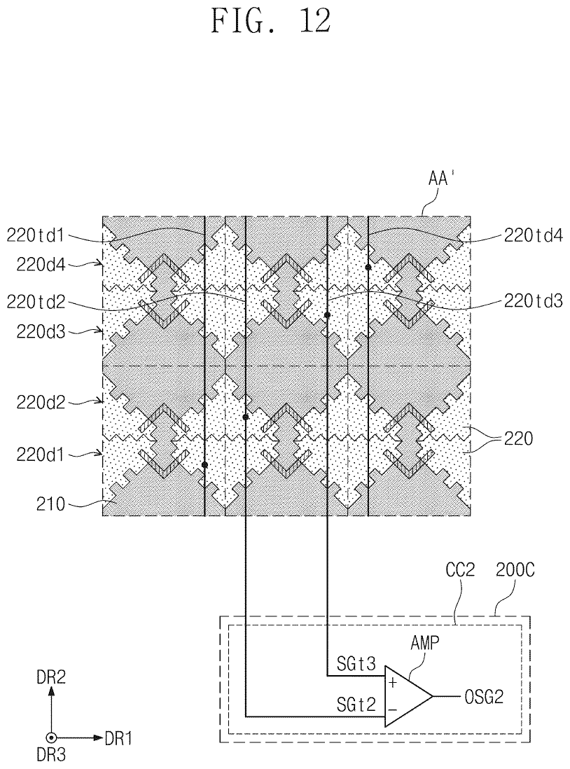

FIG. 11 is a waveform diagram illustrating a second signal SGt2 and a third signal SGt3 according to an embodiment of the present disclosure. FIG. 12 is a view illustrating an operation of a second circuit CC2 according to an embodiment of the present disclosure.

FIG. 11 illustrates third sections T3 overlapping with each other in time. FIG. 12 illustrates the area AA′ of the sensor layer 200 illustrated in FIG. 6, and a portion of the sensor driver 200C. In FIG. 12, the same reference numerals are used to denote the same or substantially the same (or similar) elements as those described above with reference to FIG. 6, and thus, redundant description thereof may not be repeated hereinafter.

Referring to FIGS. 2, 5, 11, and 12, the sensor driver 200C may include the second circuit CC2. The second circuit CC2 may be a circuit to remove a noise. As an example, the second circuit CC2 may perform a differential operation on the signal provided from the second division electrode 220d2 of one second electrode 220-1, and the signal provided from the third division electrode 220d3 of another second electrode 220-2. The signal provided from the second division electrode 220d2 may be the second signal SGt2, and the signal provided from the third division electrode 220d3 may be the third signal SGt3. The second circuit CC2 may remove the noise of the third signal SGt3.

The second signal SGt2 may be a signal provided through the second division trace line 220td2 electrically connected to the second division electrode 220d2, and the third signal SGt3 may be a signal provided through the third division trace line 220td3 electrically connected to the third division electrode 220d3. As described above, the third division electrode 220d3 and the fourth division electrode 220d4 included in another second electrode 220-2 among the second electrodes 220 may be referred to as the first division electrode and the second division electrode, respectively, and thus, the third signal SGt3 may be referred to as the first signal.

The second division trace line 220td2 and the third division trace line 220td3 may overlap with the display area 100DA (e.g., refer to FIG. 4) of the display layer 100. Accordingly, a noise may occur in the second division trace line 220td2 and the third division trace line 220td3 according to the operation of the display layer 100. According to an embodiment, the second circuit CC2 may include an amplifier AMP to remove the noise. The amplifier AMP may receive the second signal SGt2 from the second division electrode 220d2 and the third signal SGt3 from the third division electrode 220d3, and may perform a differential operation on the second signal SGt2 and the third signal SGt3 to generate a differential amplified signal OSG2. In this case, the second signal SGt2 may be used as a differential signal of the third signal SGt3 that is a signal of a next channel. As the second signal SGt2 and the third signal SGt3 are differentially operated, the noise in the second signal SGt2 and the third signal SGt3 may be removed.

In FIG. 12, the second signal SGt2 provided through the second division trace line 220td2 electrically connected to the second division electrode 220d2 and the third signal SGt3 provided through the third division trace line 220td3 electrically connected to the third division electrode 220d3 are illustrated as a representative example, but the present disclosure is not limited thereto. According to an embodiment, a signal provided through one division trace line may be used as a differential signal of a signal provided through another division trace line of a next channel, and thus, the differential amplified signal may be generated through the differential operation. Accordingly, the noise in the signal may be removed through the differential operation.

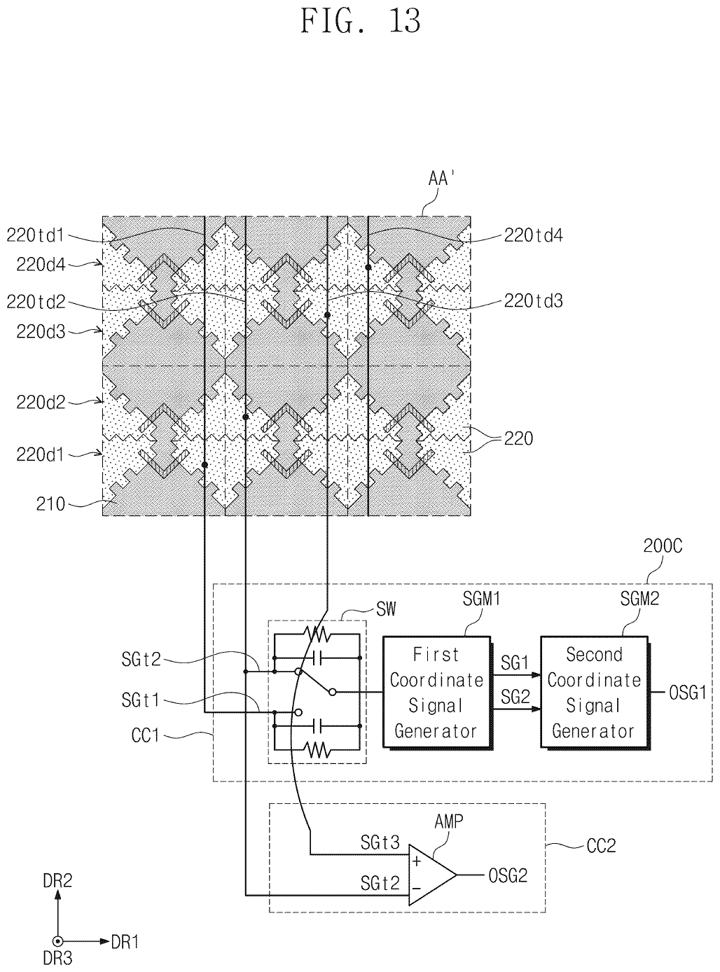

FIG. 13 is a view illustrating an operation of the first circuit CC1 and the second circuit CC2 according to an embodiment of the present disclosure. In FIG. 13, the same reference numerals are used to denote the same or substantially the same (or similar) elements as those described above with reference to FIGS. 10 and 12, and thus, redundant description thereof may not be repeated hereinafter.

Referring to FIGS. 9, 11, and 13, the sensor driver 200C may include the first circuit CC1 and the second circuit CC2.

The first circuit CC1 and the second circuit CC2 may be concurrently (e.g., simultaneously or substantially simultaneously) operated with each other. As an example, the third section T3 in which the second circuit CC2 is operated may temporarily overlap with at least a portion of the first section T1 or the second section T2 in which the first circuit CC1 is operated. In this case, the third section T3 may temporarily overlap with the first section T1 or the second section T2, and the third section T3 may temporarily overlap with both the first section T1 and the second section T2. In addition, the third section T3 may temporarily overlap with only a portion of the first section T1 or the second section T2.

According to an embodiment, the first circuit CC1 and the second circuit CC2 may be sequentially operated. As an example, the second circuit CC2 may be operated after the operation of the first circuit CC1. In this case, the third section T3 in which the second circuit CC2 is operated may be after the first section T1 and the second section T2 in which the first circuit CC1 is operated.

According to an embodiment, at least one of the first circuit CC1 or the second circuit CC2 may be omitted as needed or desired. Accordingly, the sensor driver 200C may include either the first circuit CC1 or the second circuit CC2.

The electronic or electric devices and/or any other relevant devices or components according to embodiments of the present disclosure described herein (e.g., the first coordinate signal generator, the second coordinate signal generator, and the like) may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. An electronic device comprising:
a sensor layer comprising a sensing area, and a peripheral area adjacent to the sensing area; and
a sensor driver electrically connected to the sensor layer, the sensor layer comprising:
a plurality of first electrodes along a first direction;
a plurality of second electrodes along a second direction crossing the first direction;
a plurality of first trace lines electrically connected to the first electrodes; and
a plurality of second trace lines electrically connected to the second electrodes, and partially located in the peripheral area,
wherein each of the second electrodes comprises:
a first division electrode extending in the first direction; and
a second division electrode extending in the first direction, and spaced from the first division electrode in the second direction, and
wherein the sensor driver comprises a first circuit configured to:
receive a first signal from the first division electrodes of the second electrodes to generate a first intermediate coordinate signal;
receive a second signal from the second division electrodes of the second electrodes to generate a second intermediate coordinate signal; and
generate a coordinate signal based on the first intermediate coordinate signal and the second intermediate coordinate signal.

2. The electronic device of claim 1, wherein the first circuit comprises a switch circuit configured to selectively receive either the first signal or the second signal.

3. The electronic device of claim 2, wherein the first circuit further comprises a first coordinate signal generator configured to receive the first signal through the switch circuit in a first section to generate the first intermediate coordinate signal, and receive the second signal in a second section following the first section in time to generate the second intermediate coordinate signal.

4. The electronic device of claim 3, wherein the first circuit further comprises a second coordinate signal generator configured to calculate a centroid of the first intermediate coordinate signal and the second intermediate coordinate signal to generate the coordinate signal.

5. The electronic device of claim 1, wherein the sensor driver further comprises a second circuit comprising an amplifier configured to perform a differential operation on the second signal provided from the second division electrode of one second electrode among the second electrodes, and the first signal provided from the first division electrode of another second electrode among the second electrodes to generate a differential amplified signal.

6. The electronic device of claim 1, wherein the second trace lines extend in the second direction in an area overlapping with the sensing area.

7. The electronic device of claim 1, wherein the second trace lines have a same length as each other in an area overlapping with the sensing area.

8. The electronic device of claim 1, wherein the sensing area comprises a plurality of sensing units along the first direction and the second direction, and each of the sensing units overlaps with one first electrode among the first electrodes and one second electrode among the second electrodes.

9. The electronic device of claim 1, wherein a first maximum width in the second direction of the first division electrode is smaller than a second maximum width in the first direction of one first electrode among the first electrodes.

10. The electronic device of claim 1, wherein the first division electrode comprises:
a plurality of sensing patterns spaced from each other in the first direction; and
a plurality of bridge patterns located at a different layer from that of the sensing patterns, and electrically connected to the sensing patterns, and
wherein the second trace lines are located at a same layer as that of the bridge patterns.

11. The electronic device of claim 10, wherein the second trace lines comprise:
a first division trace line connected to the first division electrode of one second electrode among the second electrodes; and
a second division trace line connected to the second division electrode of the one second electrode, and
wherein the first division trace line and the second division trace line are located between two bridge patterns that are closest to each other in the first direction among the bridge patterns.

12. The electronic device of claim 11, wherein the second trace lines comprise:
a third division trace line connected to the first division electrode of another second electrode among the second electrodes; and
a fourth division trace line connected to the second division electrode of the another second electrode, and
wherein a first distance between the first division trace line and the second division trace line is smaller than a second distance between the second division trace line and the third division trace line in an area overlapping with the sensing area.

13. An electronic device comprising:
a sensor layer comprising a sensing area, and a peripheral area adjacent to the sensing area; and
a sensor driver electrically connected to the sensor layer, the sensor layer comprising:
a plurality of first electrodes along a first direction;
a plurality of second electrodes along a second direction crossing the first direction;
a plurality of first trace lines electrically connected to the first electrodes; and
a plurality of second trace lines electrically connected to the second electrodes, and partially located in the peripheral area,
wherein one second electrode among the second electrodes comprises:
a first division electrode; and
a second division electrode spaced from the first division electrode in the second direction,
wherein another second electrode among the second electrodes comprises:
a third division electrode; and
a fourth division electrode spaced from the third division electrode in the second direction,
wherein the first division electrode, the second division electrode, the third division electrode, and the fourth division electrode are sequentially located along the second direction, and
wherein the sensor driver is configured to perform a differential operation on a signal received from the second division electrode and a signal received from the third division electrode.

14. The electronic device of claim 13, wherein the sensor driver further comprises an amplifier configured to perform the differential operation on the signal received from the second division electrode and the signal received from the third division electrode to generate a differential amplified signal.

15. The electronic device of claim 13, wherein the sensor driver further comprises a first coordinate signal generator configured to:
generate a first intermediate coordinate signal based on a signal provided from the first division electrode; and
generate a second intermediate coordinate signal based on the signal provided from the second division electrode.

16. The electronic device of claim 15, wherein the sensor driver further comprises a second coordinate signal generator configured to calculate a centroid of the first intermediate coordinate signal and the second intermediate coordinate signal to generate a coordinate signal.

17. The electronic device of claim 15, wherein the sensor driver comprises a switch circuit configured to selectively receive the signal from either the first division electrode or the second division electrode.

18. The electronic device of claim 13, wherein a first maximum width in the second direction of the first division electrode is smaller than a second maximum width in the first direction of one first electrode among the first electrodes.

19. The electronic device of claim 13, wherein the second trace lines comprise:
a first division trace line connected to the first division electrode;
a second division trace line connected to the second division electrode;
a third division trace line connected to the third division electrode; and
a fourth division trace line connected to the fourth division electrode, and
wherein a first distance between the first division trace line and the second division trace line is smaller than a second distance between the second division trace line and the third division trace line in an area overlapping with the sensing area.

20. The electronic device of claim 13, wherein the second trace lines have a same length as each other in an area overlapping with the sensing area.
